(19) United States
(12) Patent Application Publication
(10) Pub. No.: US 2005/0000441 A1
(43) Pub. Date: Jan. 6, 2005

(54) Process and device for depositing in particular crystalline layers on in particular crystalline substrates

(76) Inventors: Johannes Kaeppeler, Wurselen (DE); Walter Franken, Eschweiler (DE)

Correspondence Address: ST. ONGE STEWARD JOHNSTON & REENS, LLC, 986 BEDFORD STREET, STAMFORD, CT, 06905-5619, US

(21) Appl. No.: 10/836,699

(22) Filed: Apr. 30, 2004

Related U.S. Application Data
(63) Continuation of application No. PCT/EP02/10871, filed on Sep. 27, 2002.

(30) Foreign Application Priority Data
Oct. 30, 2001 (DE) 101 53 464.9

(51) Int. Cl. C23C 16/00

(52) U.S. Cl. 118/723 E

(57) ABSTRACT

The invention relates to a method for depositing III-V semiconductor layers that also contain nitrogen, especially for depositing II-IV compounds, oxides, especially metal oxides. According to the invention, the front face of the gas inlet element and the area of the substrate holder directly opposite said front face form electrodes that can be connected or that are connected to a high frequency reactor to produce a capacitive plasma.

This application is a continuation of pending International Patent Application No. PCT/EP02/10871 filed Sep. 27, 2002 which designates the United States and claims priority of pending Germany Application No. 101 53 463.9 filed Oct. 30, 2001.

### FIELD OF THE INVENTION

The invention relates to a device and a process for depositing in particular crystalline layers on in particular crystalline substrates in a process chamber, in which at least one substrate is located on a substrate holder and into which process gases are introduced by means of a gas inlet member located opposite the substrate holder, with a first process gas emerging from a peripheral outlet opening of the gas inlet member and a second process gas emerging from an outlet opening associated with an end face, facing the substrate holder, of the gas inlet member.

A device and process of this type are described by U.S. Pat. No. 5,027,746. In the context of silicon carbide, this device is described by U.S. Pat. No. 5,788,777.

The invention is based on the object of refining the known device and the known process for the purpose of depositing III-V semiconductor layers which also contain nitrogen. A further object of the invention also relates to processes and devices for depositing II-IV compounds, oxides, in particular metal oxides, using starting materials which are difficult to decompose.

The object is achieved by the device given in claim 1 and the process given in claim 9, in which it is provided that the end face of the gas inlet member and that region of the substrate holder which lies directly opposite the end face form electrodes which, in order to generate a capacitive plasma, are or can be connected to a radio frequency generator. The radio frequency field which is built up between the end face of the gas inlet member and the electrode lying opposite the end face results in the formation of the plasma there. This plasma is disposed in the region in which the outlet openings for the second process gas are located. The second process gas may, for example, include ammonia. The ammonia decomposes in the plasma, so that nitrogen radicals are formed. This selective preliminary decomposition of the nitrogen components supplied in gas form means that the process chamber temperature can be kept very low. It may, for example, be 500° C. On account of the fact that the gas inlets are separated into a first, peripheral outlet opening and a second outlet opening associated with the electrode, a selective plasma is formed. The gases which emerge from the peripheral outlet opening and are, for example, trimethylgallium, trimethylindium or other metalorganic components, are not decomposed by the plasma. It is also possible for another group V component in the form of a hydride, for example arsine or phosphine, to emerge through the central outlet opening, which is associated with the electrode. These gases can also undergo preliminary decomposition in the plasma. According to a preferred development of the invention, the substrate holder can be driven in rotation by a drive shaft. This drive shaft may be associated with the supply leading to the electrode formed by the center of the substrate holder. The electrode can then rotate with respect to the other electrode. This leads to a symmetrical plasma being generated. The substrate holder which can be driven in rotation preferably carries a multiplicity of substrates which are disposed about its center and are in particular located on substrate carrier plates which can themselves be driven in rotation. The substrate carrier plates may be located on a gas cushion. The outlet nozzles which serve to form the gas cushion can be directed in such a way that they set the substrate carrier plate in rotation. In a further configuration, it is provided that the electrode associated with the substrate holder is formed by a clamping or tension piece, by means of which an annular section of the substrate holder is pressed onto a carrying element. It is also possible for an annular section, which is formed as an insulating body, to be disposed between the clamping or tensioning piece.

This annular section may, for example, consist of quartz. The end face of the gas inlet member which forms the electrode may have a metal plate. This metal plate may form openings, from which the second process gas composed of a plurality of components can emerge. A gas supply line ends to the rear of these openings. The electrical supply associated with the metal plate can run through this gas supply line. This electrical supply may be formed by a rod which is disposed in a quartz tube. The quartz tube sheaths the rod, which is screwed to the metal plate forming the electrode. The annular section of the substrate holder is heated from below or the rear by a radio frequency coil in a known way. The tensioning piece and/or the metal plate forming the electrodes may be made from molybdenum. The plasma is generated by a plasma generator. The plasma generator generates an AC voltage of, for example, 13.56 MHz. This AC voltage is introduced capacitively into the gas phase of the process chamber via the two electrodes. A symmetrical, selective plasma which acts only on the hydride burns between the electrodes. As an alternative to ammonia, it is also possible to use other nitrogen compounds, for example hydrazine or the like.

### BRIEF DESCRIPTION OF DRAWINGS

An exemplary embodiment of the invention is explained below on the basis of appended figures, in which:

FIG. 1 shows a highly diagrammatic sectional illustration of a cross section through a process chamber with the two electrodes and the electrical supplies leading to the electrodes,

FIG. 2 shows a section on the line 11-11 in FIG. 1,

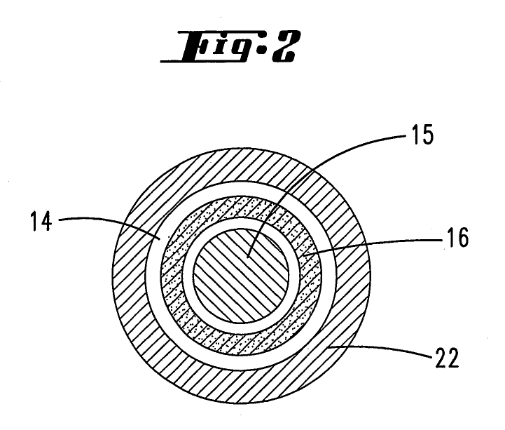

FIG. 3 shows an enlarged illustration of the region of the process chamber in which the electrodes are disposed,

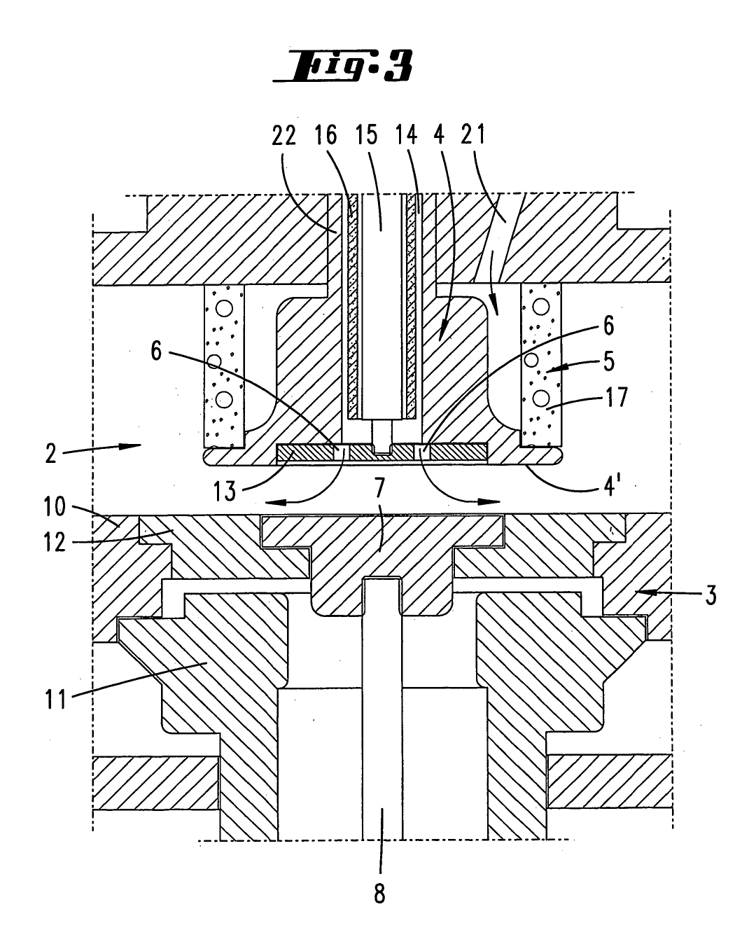

FIG. 4 shows an enlarged illustration of the head of the gas inlet system.

### DETAILED DESCRIPTION OF EMBODIMENTS

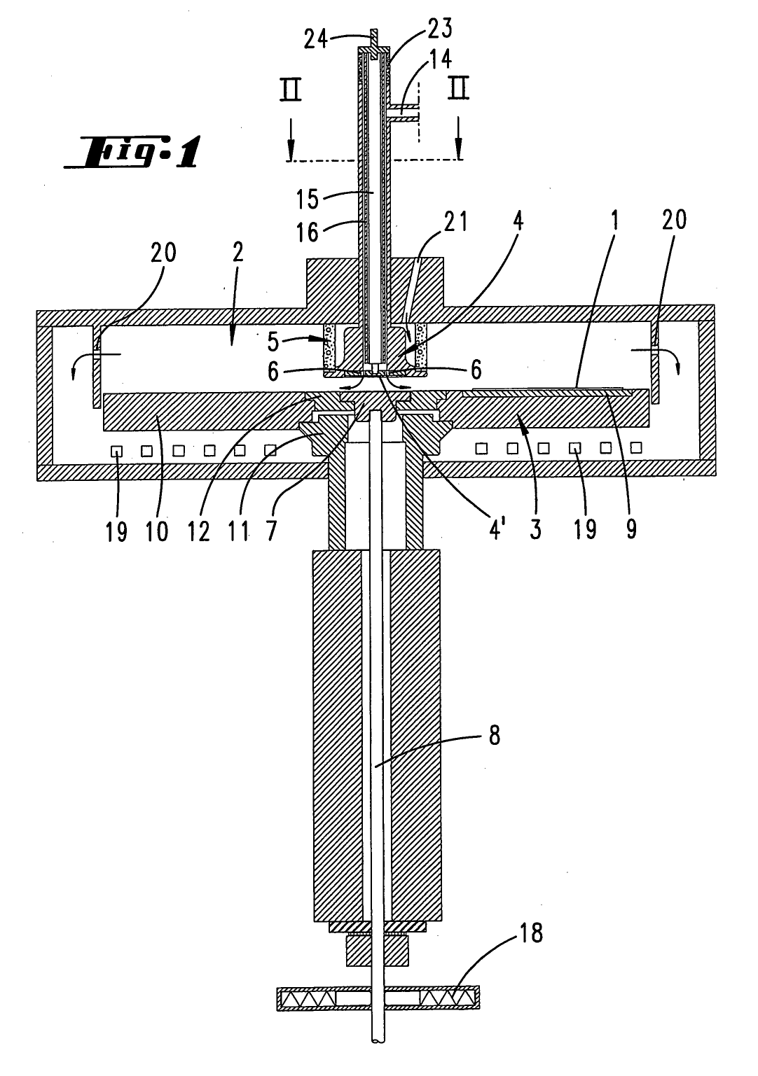

The reactor which is illustrated highly diagrammatically in FIG. 1 has a substantially cylinder-symmetrical process chamber 2. The base of the process chamber 2 is formed by a substrate holder 3, which may consist of graphite or coated graphite. The substrate holder 3 has an outer, annular section 10, on which a multiplicity of substrate holder plates 9 are disposed. The substrate holder plates 9 surround the center of the annular section in planetary manner. The substrate holder plates can be driven in rotation by means of means which are not shown. These are gas nozzles which are disposed beneath the substrate holder plates 9 and from which a targeted gas stream emerges, so as firstly to form a gas cushion on which the substrate holder plates 9 float and secondly to exert a torque on the substrate holder plates 9, so that the substrate holder plates 9 rotate about their axes. A substrate 1 is located on each of the substrate holder plates 9, which are located in cut-outs.

The inner edge of the annular section 10 is supported on a carrying element 11. The carrying element 11 is mechanically driven in rotation by means which are not shown. Above the carrying element 11 there is a likewise annular insulating body, which is supported on the inner edge of the annular section 10. A tensioning piece 7 made from molybdenum is supported on the inner edge of the insulating body 12. The surfaces of the annular section 10, insulating body 12 and tensioning piece 7 are flush with one another. A tensioning rod 8 is screwed into a rear screw-in opening in the tensioning piece 7. This tensioning rod 8 is part of a drive shaft which drives the substrate holder 3 in rotation.

Opposite the tensioning piece 7, which forms the center of the substrate holder 3, there is a gas inlet member 4. This gas inlet member 4 projects into the process chamber 2. The gas inlet member 4 has a peripheral outlet opening 5 in the form of a porous or slotted quartz ring. A first process gas flows out of this outlet opening 5. This first process gas is a metalorganic compound of a metal belonging to the third main group, for example trimethylgallium or trimethylindium. To the rear of this porous ring 17 there is a gas distribution chamber, into which the metalorganic compound and a carrier gas, which may be hydrogen or nitrogen, flow through a supply line 21.

The end face 4′ of the gas inlet member 4 carries a metal plate 13. This metal plate 13 is located directly opposite the tensioning piece, which likewise consists of metal. The metal plate 13 has a plurality of openings 6, in particular disposed in the form of a ring. The external screw thread of a holding rod 15 is screwed into the center of the metal plate. The holding rod 15 is sheathed by means of a quartz tube 16. Outside the quartz tube 16 and inside a wall of a cavity in which the quartz tube 16 is located, the second process gas flows to the openings 6. The flow passage 14 for this second process gas, which is a hydride, is annular.

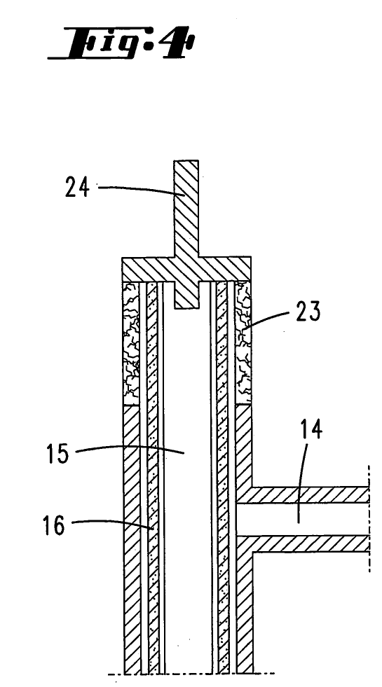

The head of the gas inlet member 4 is illustrated on an enlarged scale in FIG. 4. An insulation sleeve 23, which is closed off by a cover, is seated on the tubular casing 22. This cover forms an electrical connection 24 for the plasma generator. The electrical supply 15 is secured to the inner side of the cover, for example by means of a threaded connection. The end of the quartz tube 16 butts against the inner surface of the cover.

The process gas which flows through the supply line 14 contains a nitrogen compound, for example ammonia. This ammonia passes through the openings 6 into the space between the metal plate 13 and the metallic tensioning piece 7.

A radio frequency AC voltage, for example of 13.56 MHz, is applied to the metal plate 13 and the tensioning piece 7. The total gas pressure in the process chamber 2 is selected in such a way that a symmetrical plasma burns between the stationary metal plate 13 and the tensioning piece 7. This is a capacitive plasma. Within the plasma, the nitrogen compound and, for example, arsine or phosphine, which is additionally introduced into the reactor through the gas supply line 14, undergoes preliminary decomposition, so that in particular nitrogen radicals are formed.

The electrical supply to the metal plate 13, which preferably consists of molybdenum, is effected via the rod 15.

The electrical supply to the tensioning piece 7, which likewise preferably consists of molybdenum, is effected by means of the tensioning rod 8. The end of the tensioning rod 8 may project out of the drive shaft. Sliding contacts 18 can engage on the tensioning rod 8 in order to transfer the electric current.

Beneath the annular section 10 of the substrate holder 3 there is a coil 19, which is likewise acted upon by radio frequency. Induced eddy currents heat the annular section 10 of the substrate holder 3.

A wall which forms gas outlet openings 20 extends around the process chamber 2.

The process gas which emerges from the openings 6 is partially decomposed in the plasma between the two electrodes 7 and 13. A gas stream flowing radially outward conveys the nitrogen radicals formed to the substrates 1. The metalorganic component emerges through the peripheral outlet opening 5 and is decomposed in the region in front of or above the substrate 1. A layer of a III-V material, for example GaAs or InP, is deposited on the substrates 1. At the same time, a small quantity of nitrogen is incorporated into the crystal layer. It is considered advantageous for the electrodes to rotate relative to one another.

The position of the plasma between the two electrodes 7 and 13 disposed in the center of the substrate holder 3 is selected in such a way that the plasma only contributes to the decomposition of those gases which flow out of the outlet openings 6. The plasma is spatially remote from the substrates 1 and the substrate holder plates 9. Furthermore, it is advantageous for the gas which is to be decomposed to flow into the zone between the two electrodes 7 and 13 in the axial direction through the outlet openings 6. The gas is diverted in the region between the electrodes 7 and 13, in order to leave the plasma, which is restricted to the region between the two electrodes 7, 13, in the radially outward direction. Furthermore, it is advantageous for the electrode 7 to rotate relative to the electrode 13 associated with the gas inlet member 4. This leads to homogenization of the plasma. Since, furthermore, the entire substrate holder 3 rotates with respect to the gas inlet member 4 and the electrode 13, the distribution of gas to the individual substrates 1 is further homogenized.

Moreover, it is advantageous for the peripheral outlet opening 5 to be disposed directly below the process chamber cover and for the axial outlet openings 6 and/or the region in which the plasma is generated to directly adjoin the base of the process chamber, i.e. the substrate holder 3.

In structural terms, it is advantageous if the upper supply to the electrode 13 is effected by means of a tensioning rod 15 and the supply to the lower electrode 7 is likewise effected by means of a tensioning rod 18, in which case the two tensioning rods are connected to the associated electrode via a screw thread, with one electrode being formed by the metal plate 13 and the other electrode being formed by a tensioning piece 7.

All the features disclosed are (inherently) pertinent to the invention. The content of disclosure of the associated/appended priority documents (copy of the prior application) is hereby incorporated in its entirety in the disclosure of the present application, partly for the purpose of incorporating features of these documents into claims of the present application.

1. Device for depositing in particular crystalline layers on in particular crystalline substrates, having a process chamber with a substrate holder for accommodating a multiplicity of substrates, disposed around a center of the substrate holder, and a gas inlet member, which is located opposite the substrate holder and has a peripheral outlet opening for a first process gas and an outlet opening for a second process gas disposed at an end face facing the substrate holder, characterized in that the end face of the gas inlet member and that region of the substrate holder which lies directly opposite the end face form electrodes which, in order to generate a capacitive plasma, are or can be connected to a radio frequency generator, with the plasma being restricted to the center, remote from the substrates, of the substrate holder.

2. Device according to claim 1 or in particular according thereto, characterized in that the substrate holder, together with its associated electrode, can be driven in rotation, and the electrode located directly opposite the electrode which can be driven in rotation is stationary.

3. Device according to claim 1, characterized in that the substrate holder can be driven in rotation by a drive shaft, and the drive shaft has a tension rod which acts on a tension piece disposed in the center of the substrate holder and which is an electrical supply to the electrode formed by the tension piece.

4. Device according to claim 1, characterized in that the substrate holder which can be driven in rotation carries has a multiplicity of substrate holder carrier plates, which are disposed about its center and can themselves be driven in rotation, for accommodating the substrates.

5. Device according to claim 1, characterized in that the electrode associated with the substrate holder is formed by a tension piece which presses an annular section of the substrate holder onto a carrying element.

6. Device according to claim 1, characterized by an annular insulating body disposed between the tension piece and the annular section.

7. Device according to claim 1, characterized in that the electrode associated with the end face of the gas inlet member is a metal plate which has gas outlet openings and to the rear of which ends a gas supply line, through which the supply associated with the electrode runs.

8. Device according to claim 1, characterized in that the electrical supply is configured as a rod which is sheathed by a quartz tube and by means of which the electrode plate is secured to the gas inlet member.

9. Device according to claim 1, characterized in that the annular section can be heated at the rear, in particular by means of radio frequency (19).

10. Process for depositing in particular crystalline layers on in particular crystalline substrates in a process chamber, in which at least one substrate is located on a substrate holder and into which process gases are introduced by means of a gas inlet member located opposite the substrate holder, with a first process gas emerging from a peripheral outlet opening and a second process gas emerging from an outlet opening associated with an end face, facing the substrate holder, of the gas inlet member, characterized by a capacitive plasma, which is generated between the end face of the gas inlet member and that region of the substrate holder which lies directly opposite the end face, for decomposing the process gas which emerges from the end-face openings.

11. Process according to claim 10, characterized in that the process gas emerging from the end-face opening is ammonia or another nitrogen compound.

12. Process according to claim 10, characterized in that the process temperature is 500° C.

13. Process according to claim 10, characterized in that the process gas which emerges from the end-face opening is a starting material for the deposition of oxides, in particular metal oxides, which starting material is difficult to decompose at low temperatures.
